(19) United States
(12) Patent Application Publication
(10) Pub. No.: US 2011/0050121 A1
(43) Pub. Date: Mar. 3, 2011

(54) LIGHT EMITTING DEVICE USING DIODE STRUCTURE CONTROLLED BY DOUBLE GATE, AND SEMICONDUCTOR APPARATUS INCLUDING THE SAME

(76) Inventors: Youngjune Park, Seoul (KR); Hunsuk Kim, Seoul (KR); Seokha Lee, Chungcheongnam-do (KR); Byunghak Cha, Seoul (KR); Kangmu Lee, Gyeonggi-do (KR); Junho Chun, Seoul (KR); Sunghoon Kwon, Seoul (KR); Chanhyeong Park, Seoul (KR); Inyoung Jeong, Gyeonggi-do (KR)

(21) Appl. No.: 12/812,816

(22) PCT Filed: Jan. 14, 2009
(86) PCT No.: PCT/KR09/00189

§ 371 Date: Jul. 14, 2010

(30) Foreign Application Priority Data
Jan. 14, 2008 (KR) 10- 2008-0003994
Sep. 2, 2008 (KR) 10-2008-0086433

(51) Int. Cl. H05B 37/02; H01L 33/36; H01L 33/34; H01L 29/78; H01L 31/153

(52) U.S. Cl. 315/294; 257/79; 257/103; 257/366; 257/290; 315/291; 257/E33.077

(57) ABSTRACT

A light emitting device is provided. The light emitting device includes a p-type semiconductor, an n-type semiconductor, a semiconductor film connected between the p-type semiconductor and the n-type semiconductor, a first electrode disposed on the semiconductor film and configured to apply an electric field to the semiconductor film, and a second electrode disposed under the semiconductor film and configured to apply an additional electric field to the semiconductor film.

### TECHNICAL FIELD

The described technology relates to a light emitting device and a semiconductor device including the same, and more particularly, to a light emitting device using a diode structure controlled by a double gate and a semiconductor device including the same.

### BACKGROUND ART

In recent years, research has been conducted on light emitting devices using silicon instead of compound semiconductors. One such research result is disclosed by Shin-ichi SAITO et al. in the Japanese Journal of Applied Physics, Vol. 45, No. 27, 2006, pp. L679-L682. In the above-described paper, a light emitting device includes a PN junction formed in a silicon material to a very small thickness of about 10 nm to overcome an indirect bandgap characteristic of the silicon through quantum confinement and enable emission in a PN junction surface.

The light emitting device disclosed in the paper substantially performs linear emission. That is, since the emission is performed in the PN junction surface, the emission is performed in a narrow region defined by the length of the PN junction surface and the very small thickness of the silicon material. When the emission is performed in the narrow region, since the resistance of the light emitting device is increased, a high voltage must be applied to the light emitting device, thus increasing power consumption. Also, when the emission is performed in the narrow region, obtaining high luminance may be more difficult than when emission is performed in a wide region.

Despite the above-described drawbacks, since the manufacture of light emitting devices using silicon can adopt standard complementary metal-oxide-semiconductor (CMOS) process technology, the light emitting devices may be produced more economically. Thus, the industrial demand for techniques of forming light emitting devices using silicon is increasing.

### DISCLOSURE

### Technical Solution

In one embodiment, a light emitting device is provided. The light emitting device includes: a p-type semiconductor; an n-type semiconductor; a semiconductor film connected between the p-type semiconductor and the n-type semiconductor; a first electrode disposed on the semiconductor film and configured to apply an electric field to the semiconductor film; and a second electrode disposed under the semiconductor film and configured to apply an additional electric field to the semiconductor film.

In another embodiment, a light emitting method is provided. The light emitting method includes: (a) providing a p-type semiconductor, an n-type semiconductor, and a semiconductor film connected between the p-type and n-type semiconductors; and (b) applying a voltage for allowing the flow of a forward current to the p-type and n-type semiconductors, allowing one of inversion and accumulation to occur in an upper portion of the semiconductor film, and allowing the other of the inversion and the accumulation to occur in a lower portion of the semiconductor film to permit the semiconductor film to emit light.

In still another embodiment, a light emitting method is provided. The light emitting method includes: (a) providing a p-type semiconductor, an n-type semiconductor, and a semiconductor film connected between the p-type and n-type semiconductors; and (b) applying a voltage for allowing the flow of a forward current to the p-type and n-type semiconductors and allowing occurrence of tunneling between upper and lower portions of the semiconductor film to permit the semiconductor film to emit light.

In yet another embodiment, a semiconductor device including an aggregate of at least two unit devices is provided. Each of the unit devices includes: a semiconductor region; source and drain regions disposed on both end sides of the semiconductor region and configured to provide or collect one of electrons and holes; a first insulator disposed on the semiconductor region; a first electrode disposed on the first insulator and configured to change a distribution state of one of the electrons and the holes in an upper portion of the semiconductor region; a second insulator disposed under the semiconductor region; and a second electrode disposed under the second insulator and configured to change a distribution state of one of the electrons and the holes in a lower portion of the semiconductor region. The first and second electrodes of each of the at least two unit devices are alternately arranged to form the aggregate.

In yet another embodiment, a method of driving a semiconductor device is provided. The method includes: (a) providing an aggregate including at least two unit devices, each unit device including a semiconductor region, source and drain regions disposed on both end sides of the semiconductor region, and a first electrode and a second electrode disposed in upper and lower portions of the semiconductor region; (b) applying a voltage to allow the flow of a forward current between the source and drain regions of the unit device; and (c) applying a voltage to each of the first and second electrodes of the unit device to respectively change distribution states of electrons and holes in the upper and lower portions of the semiconductor region. The first and second electrodes of the at least two unit devices are alternately arranged to form the aggregate.

In yet another embodiment, a method of driving a semiconductor device is provided. The method includes: (a) providing an aggregate including at least two unit devices, each unit device including a semiconductor region, source and drain regions disposed on both end sides of the semiconductor region, and first and second electrodes disposed in upper and lower portions of the semiconductor region; and (b) applying light to the unit device to generate electron-hole pairs. The first and second electrodes of the at least two unit devices are alternately arranged to form the aggregate.

### BRIEF DESCRIPTION OF DRAWINGS

FIG. 1 is a cross-sectional view schematically illustrating a light emitting device according to one embodiment of the disclosed technology.

FIG. 2 is a cross-sectional view taken along line A-A′ of the light emitting device of FIG. 1.

FIG. 3 is a diagram of a light emitting device according to one embodiment, which illustrates an embodied example of a light emitting device using a silicon-on-insulator (SOI) wafer.

FIGS. 4 through 8 are diagrams illustrating respective steps of a method of manufacturing a light emitting device according to one embodiment.

FIG. 9 is a diagram of a light emitting device according to another embodiment.

FIG. 10 is a schematic cross-sectional view of a unit device of a semiconductor device according to one embodiment of the disclosed technology.

FIG. 11 is a cross-sectional view taken along line A-A′ of FIG. 10.

FIG. 12 is a diagram schematically illustrating a method of operating a unit device according to one embodiment.

FIG. 13 is a diagram schematically illustrating a semiconductor device as an aggregate of at least two unit devices according to one embodiment.

FIGS. 14, 16, 18, 20, 22, 24, and 26 are plan views schematically illustrating a method of manufacturing a semiconductor device according to one embodiment.

FIGS. 15, 17, 19, 21, 23, 25, and 27 are cross-sectional views schematically illustrating a method of manufacturing a semiconductor device according to one embodiment.

### MODE FOR EMBODYING INVENTION

Hereinafter, embodiments of the present technology will be described in detail. However, the present technology is not limited to the embodiments disclosed below, but can be implemented in various types. Therefore, the present embodiments are provided for complete disclosure of the present technology and to fully inform the scope of the present technology to those ordinarily skilled in the art. In the drawings, the widths or thicknesses of layers and regions are exaggerated for clarity. The drawings are generally described from the viewpoint of an observer. It will also be understood that when a layer is referred to as being “on or under” another layer or substrate, it can be directly on or directly under the other layer or substrate or intervening layers may also be present.

### Light Emitting Device Using Diode Controlled by Double Gate

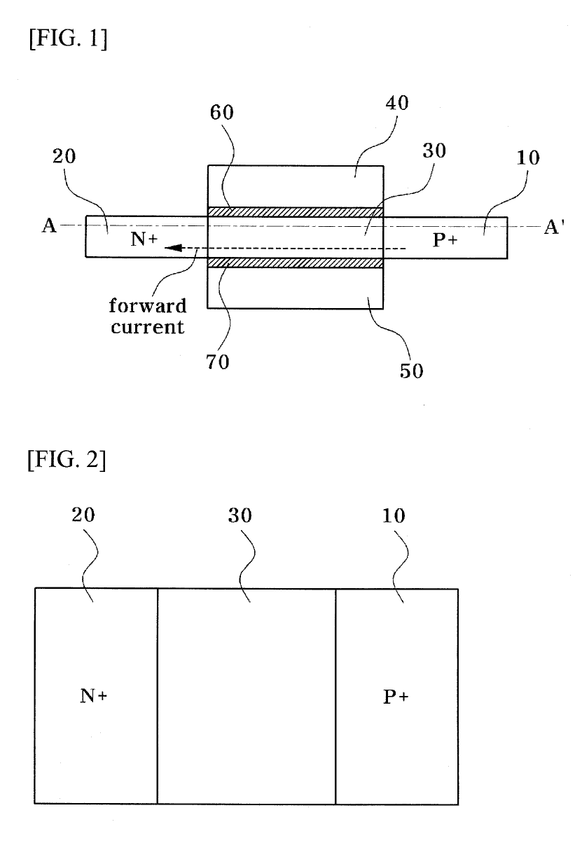

FIG. 1 is a cross-sectional view schematically illustrating a light emitting device according to one embodiment of the disclosed technology, and FIG. 2 is a cross-sectional view taken along line A-A′ of the light emitting device of FIG. 1.

Referring to FIGS. 1 and 2, a light emitting device includes a p-type semiconductor 10, an n-type semiconductor 20, a semiconductor film 30, a first electrode 40, a second electrode 50, a first insulator 60, and a second insulator 70.

For example, each of the p-type semiconductor 10 and the n-type semiconductor 20 may be heavily doped silicon. Each of the p-type and n-type semiconductors 10 and 20 may be connected to a lateral surface of the semiconductor film 30.

The semiconductor film 30 may be connected between the p-type and n-type semiconductors 10 and 20. For example, the semiconductor film 30 may be p-type or n-type doped silicon. In order to facilitate tunneling, the semiconductor film 30 may have a thickness of several to several tens of nm or less. For example, the semiconductor film 30 may have a thickness of about 20 nm or less.

The first electrode 40 is disposed on the semiconductor film 30 and applies an electric field to the semiconductor film 30. To do this, a first voltage is applied to the first electrode 40. The first electrode 40 may be formed of, for example, a metal or doped semiconductor (e.g., polycrystalline silicon (poly-Si)).

The second electrode 50 is disposed under the semiconductor film 40 and applies an additional electric field to the semiconductor film 30. To do this, a second voltage is applied to the second electrode 50. The second voltage may have a different value from the first voltage. For example, the second electrode 50 may be formed of a metal or doped semiconductor (e.g., poly-Si or silicon substrate).

The first insulator 60 is disposed between the first electrode 40 and the semiconductor film 30. The first insulator 60 may be, for example, silicon oxide (SiO₂) or silicon nitride (Si₃N₄).

The second insulator 70 is disposed between the second electrode 50 and the semiconductor film 30. The second insulator 70 may be, for example, silicon oxide (SiO₂) or silicon nitride (Si₃N₄).

In order to permit the semiconductor film 30 to emit light, voltages are applied to the p-type semiconductor 10 and the n-type semiconductor 20 to allow the flow of a forward current (a higher voltage is applied to the p-type semiconductor than the voltage applied to the n-type semiconductor). A first voltage is applied to the first electrode 40 to allow any one of inversion and accumulation to occur in an upper portion of the semiconductor film 30, while a second voltage is applied to the second electrode 50 to allow the other one of the inversion and accumulation to occur in a lower portion of the semiconductor film 30. Under the above-described conditions, the semiconductor film 30 emits light due to electron-hole recombination caused by tunneling between the upper and lower portions of the semiconductor film 30.

The light emitting device shown in FIGS. 1 and 2 may be manufactured on a silicon-on-insulator (SOI) wafer, a SIMOX (i.e., separation by implantation of oxygen) wafer, or a bulk silicon wafer. Among these, the SIMOX wafer refers to a kind of SOI wafer including an oxide layer filled between silicon materials, which is obtained by implanting oxygen into a wafer using an ion implantation process and annealing the wafer at a high temperature.

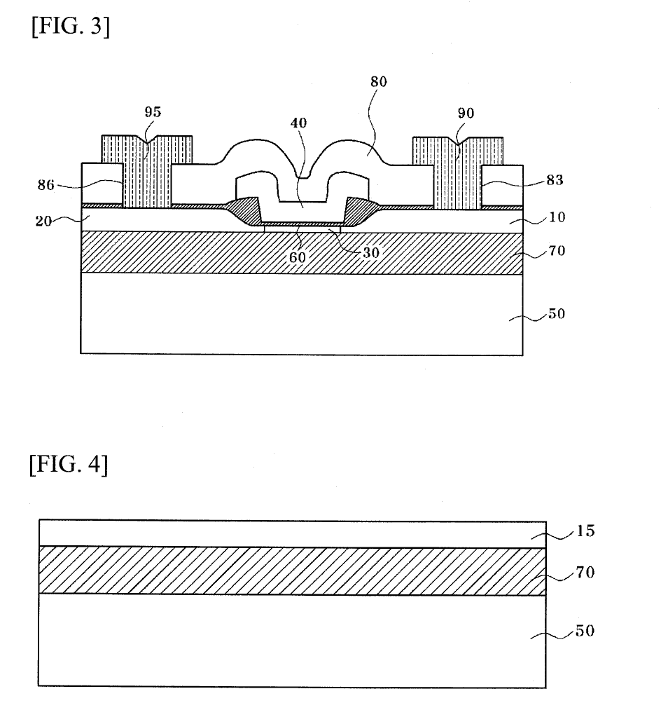

FIG. 3 is a diagram of a light emitting device according to one embodiment, which illustrates an embodied example of a light emitting device using an SOI wafer.

Referring to FIG. 3, a light emitting device includes a p-type semiconductor 10, an n-type semiconductor 20, a semiconductor film 30, a first electrode 40, a second electrode 50, a first insulator 60, and a second insulator 70. In the light emitting device of FIG. 3 according to one embodiment, the semiconductor film 30 may be a p-type semiconductor having a thickness of about 10 nm. Also, the first electrode 40 and the second electrode 50 may be embodied using a substrate formed of a semiconductor material, such as silicon or germanium and N+ poly-Si. Furthermore, the first insulator 60 and the second insulator 70 may be embodied using a thermal oxide layer and a buried oxide layer, respectively.

The light emitting device shown in FIG. 3 may further include an additional insulating layer 80 having contact holes 83 and 86, a first metal 90 contacting the p-type semiconductor 10 through the contact hole 83, and a second metal 95 contacting the n-type semiconductor 20 through the contact hole 86.

FIGS. 4 through 8 are diagrams illustrating respective steps of a method of manufacturing a light emitting device according to one embodiment.

Referring to FIG. 4, to begin with, a substrate 50 including a buried oxide layer 70 is prepared. In an embodiment shown in FIG. 4, the buried oxide layer 70 may have a thickness of, for example, about 150 nm, and a silicon material 15 formed on the buried oxide layer 70 may have a thickness of, for example, about 100 nm. Also, the substrate 50 and the silicon material 15 may be p-type doped silicon.

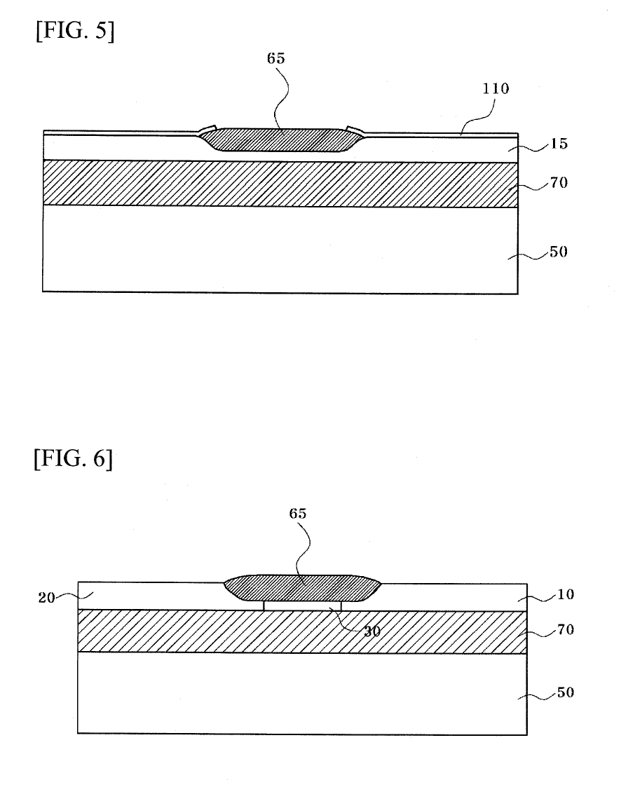

Referring to FIG. 5, after depositing and patterning a nitride layer 110, a thermal oxidation process is performed. For example, the nitride layer 110 may be formed to a thickness of about 40 nm. Due to the thermal oxidation process, an oxide layer 65 is formed to have a shape as shown in FIG. 5, and the thickness of the silicon material 15 disposed in a region where a semiconductor film is intended to be formed is reduced.

Referring to FIG. 6, after removing the nitride layer 110, p-type impurities are implanted using an ion implantation mask (not shown) into a region where the p-type semiconductor 10 is intended to be formed, thereby forming a highly doped p-type semiconductor 10. Also, n-type impurities are implanted using another ion implantation mask (not shown) into a region where the n-type semiconductor 20 is intended to be formed, thereby forming a highly doped n-type semiconductor 30.

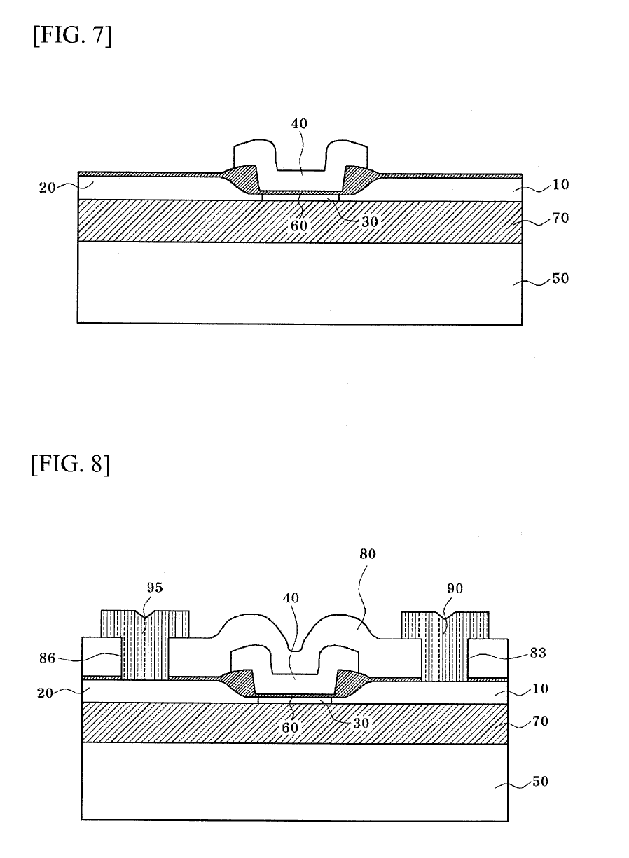

Referring to FIG. 7, after the oxide layer 65 is etched to partially expose the underlying silicon material 15, a thermal oxide layer 60 is formed on the exposed silicon material 15, and an n-type highly doped poly-Si material 40 is formed. The thermal oxide layer 60 may be formed to a thickness of, for example, about 17 nm The silicon material 15 disposed under the thermal oxide layer 60 may have a thickness of, for example, about 20 nm or less.

Referring to FIG. 8, after a low-temperature oxide layer 80 having contact holes 83 and 86 is formed, a first metal 90 is formed to contact the p-type semiconductor 10 through the contact hole 83, and a second metal 95 is formed to contact the n-type semiconductor 20 through the contact hole 86.

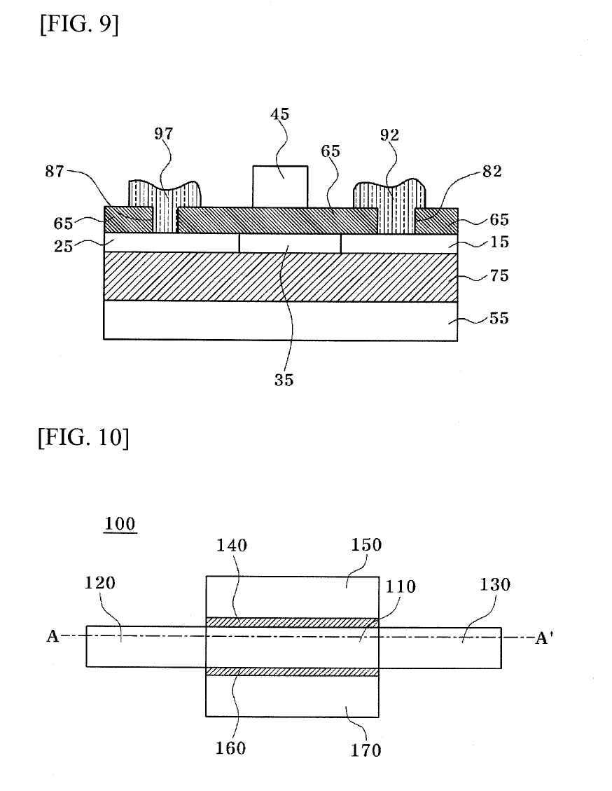

FIG. 9 is a diagram of a light emitting device according to another embodiment. Referring to FIG. 9, a light emitting device includes a p-type semiconductor 15, an n-type semiconductor 25, a semiconductor film 35, a first electrode 45, a second electrode 55, a first insulator 65 and a second insulator 75. The first electrode 45 and the second electrode 55 may be embodied using a substrate formed of a semiconductor material, such as silicon or germanium and N+ poly-Si. The first insulator 65 and the second insulator 75 may be embodied using a thermal oxide layer and a buried oxide layer, respectively.

Contact holes are formed in the first insulator 65 of the light emitting device shown in FIG. 9, and the light emitting device may further include a first metal 92 contacting the p-type semiconductor 15 through the contact hole 82 and a second metal 97 contacting the n-type semiconductor 25 through the contact hole 87.

As compared with the light emitting device described above with reference to FIGS. 3 through 8, the p-type semiconductor 15, the n-type semiconductor 25, and the semiconductor film 35 of the light emitting device according to the present embodiment may have substantially the same thickness. For example, the p-type semiconductor 15, the n-type semiconductor 25, and the semiconductor film 35 may have a thickness of about 10 nm.

### Semiconductor Device Including Unit Device Functioning as Light Emitting Device or Photodiode (PD)

According to some embodiments, a semiconductor device using the characteristics of a diode controlled by a double gate may function not only as a light emitting device described in the above embodiments with reference to FIGS. 1 through 9 but also as a PD configured to externally collect light and generate an electric signal. Hereinafter, a semiconductor device including a unit device that has a double gate and serves as a light emitting device and/or a PD will be described.

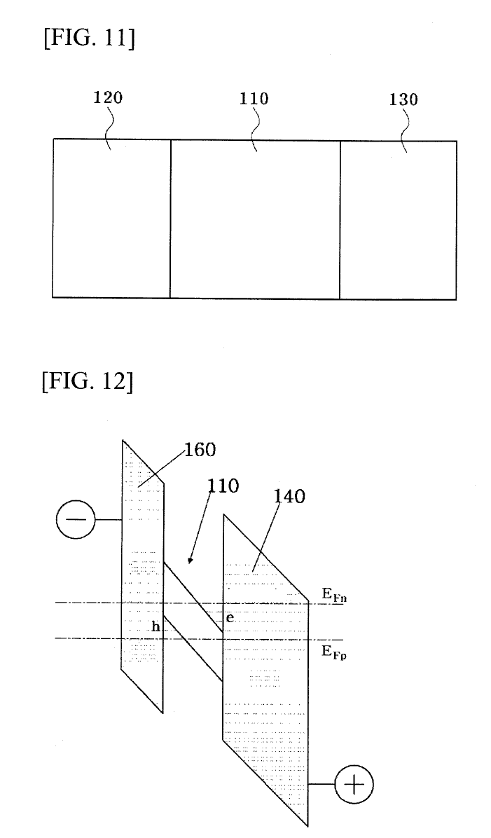

FIG. 10 is a schematic cross-sectional view of a unit device of a semiconductor device according to one embodiment of the disclosed technology, and FIG. 11 is a cross-sectional view taken along line A-N of FIG. 10.

Referring to FIGS. 10 and 11, a unit device 100 includes a semiconductor region 110, source and drain regions 120 and 130, a first insulator 140, a second insulator 160, a first electrode 150, and a second electrode 170.

The semiconductor region 110 may be formed of a semiconductor, such as silicon (Si), germanium (Ge), or gallium arsenide (GaAs). The semiconductor may be in an intrinsic state or a doped state.

According to one embodiment, the semiconductor region 110 may be formed of intrinsic silicon. According to another embodiment, the semiconductor region 110 may be formed of silicon that is lightly doped with an n-type or p-type dopant. The n-type dopant may contain phosphorus (P) or arsenic (As), and the p-type dopant may contain boron (B), aluminum (Al), or gallium (Ga). In the description of the present specification, light doping refers to doping of impurities into silicon at a concentration of about 10¹⁸ atoms/cm³ or lower.

According to other embodiments, the semiconductor region 110 may be formed in the shape of a semiconductor film. In this case, the semiconductor film may have a thickness of several to several tens of nm, for example, about 20 nm or less. Also, as described below, tunneling of electrons or holes may occur in the semiconductor film with the above-described thickness.

As shown, the source region 120 and the drain region 130 are disposed on both end sides of the semiconductor region 110. The source region 120 and the drain region 130 may provide or collect electrons or holes as conductive carriers in the unit device 100.

For example, the source and drain regions 120 and 130 may be formed of a conductive material containing a doped semiconductor, a metal, or a metal silicide. The doped semiconductor may be, for example, silicon, germanium, or gallium arsenide, which is doped with the n-type dopant or the p-type dopant.

According to one embodiment, any one of the source and drain regions 120 and 130 may be an n-type semiconductor, and the other of the source and drain regions 120 and 130 may be a p-type semiconductor. For example, the source region 120 may be formed of silicon highly doped with the n-type dopant, and the drain region 130 may be formed of silicon highly doped with the p-type dopant. In the description of the present specification, heavy doping refers to doping of impurities into silicon at a concentration of about 10²⁰ atoms/cm³ or higher. Alternatively, the source region 120 may be formed of silicon highly doped with the p-type dopant, and the drain region 130 may be formed of silicon highly doped with the n-type dopant.

According to another embodiment, the source and drain regions 120 and 130 may be formed of a metal, such as tungsten (W), aluminum (Al), titanium (Ti), or tantalum (Ta), or a metal silicide, such as tungsten silicide, titanium silicide, or tantalum silicide.

Each of the source and drain regions 120 and 130 may be connected to an additional voltage source (not shown). The voltage source applies a voltage to each of the source and drain regions 120 and 130 so that current can flow due to a potential difference caused between the source and drain regions 120 and 130. According to one embodiment, when the source region 120 is formed of silicon highly doped with the p-type dopant and the drain region 130 is formed of silicon highly doped with the n-type dopant, a higher voltage may be applied to the source region 120 than the drain region 130 so that current can flow from the source region 120 to the drain region 130. In another case, when the source region 120 is formed of silicon highly doped with the n-type dopant and the drain region 130 is formed of silicon highly doped with the p-type dopant, a higher voltage may be applied to the drain region 130 than the source region 120 so that current can flow from the drain region 130 to the source region 120.

The first insulator 140 is disposed on the semiconductor region 110. The first insulator 140 may be formed of, for example, oxide, nitride, or a combination thereof. According to one embodiment, the first insulator 140 may include silicon oxide or silicon nitride.

The first electrode 150 is disposed on the first insulator 140. For example, the first electrode 150 may be formed of doped silicon, a metal, a metal silicide, or a transparent conductive material. The doped silicon may be silicon doped with a p-type dopant, such as boron, aluminum, or gallium or silicon doped with an n-type dopant, such as phosphorus or arsenic. The metal may be, for example, tungsten (W), silver (Ag), gold (Au), copper (Cu), aluminum (Al), platinum (Pt), titanium (Ti), or tantalum (Ta). The metal silicide may be, for example, tungsten silicide, titanium silicide, or tantalum silicide. The transparent conductive material may be indium tin oxide (ITO), indium zinc oxide (IZO), zinc oxide (ZnO), or indium oxide (In₂O₃).

The first electrode 150, the first insulator 140, and the semiconductor region 110 may constitute a first metal-oxide-semiconductor (MOS) capacitor. The first electrode 150 may apply, to the semiconductor region 110, a voltage for changing a distribution state of the electrons or holes as the conductive carriers in an upper portion of the semiconductor region 110. The upper portion of the semiconductor region 110 is disposed adjacent to the first insulator 140. Specifically, the first electrode 150 may apply, to the semiconductor region 110, a predetermined voltage for forming an inversion region or accumulation region of any one of the electrons and the holes in the upper portion of the semiconductor region 110.

According to one embodiment, when the semiconductor region 110 is formed of silicon lightly doped with the p-type dopant and the first electrode 150 is formed of tungsten (W), an inversion region of the electrons may be formed in the upper portion of the semiconductor region 110 due to a predetermined positive voltage applied to the first electrode 150 on the basis of a voltage level of the semiconductor region 110. According to another embodiment, when the semiconductor region 110 is formed of silicon lightly doped with the p-type dopant and the first electrode 150 is formed of tungsten, an accumulation region of the holes may be formed in the upper portion of the semiconductor region 110 due to a predetermined negative voltage applied to the first electrode 150 on the basis of a voltage level of the semiconductor region 110.

The second insulator 160 is disposed under the semiconductor region 110. The second insulator 160 may be formed of, for example, oxide, nitride, or a combination thereof. According to one embodiment, the second insulator 160 may include silicon oxide or silicon nitride.

The second electrode 170 is disposed under the second insulator 160. The second electrode 170 may be formed of substantially the same material as the first electrode 150. Thus, a description of the second electrode 170 will be omitted for brevity.

The second electrode 170, the second insulator 160, and the semiconductor region 110 may constitute a second MOS capacitor. By applying a predetermined voltage to the second electrode 170, the distribution of the electrons or holes as the conductive carriers in the lower portion of the semiconductor region 110 disposed adjacent to the second insulator 160 may be changed. Specifically, inversion or accumulation of any one of the electrons and the holes may occur in the lower portion of the semiconductor region 110 due to the voltage applied to the second electrode 170. According to one embodiment, when the semiconductor region 110 is formed of silicon lightly doped with a p-type dopant and the second electrode 170 is a metal electrode formed of tungsten, an inversion region of the electrons may be formed in the lower portion of the semiconductor region 110 due to a predetermined positive voltage applied to the second electrode 170. According to another embodiment, when the semiconductor region 110 is formed of silicon lightly doped with a p-type dopant and the second electrode 170 is a metal electrode foamed of tungsten, an accumulation region of the holes may be formed in the lower portion of the semiconductor region 110 due to a predetermined negative voltage applied to the second electrode 170.

That is, when the semiconductor region 110 is formed of silicon lightly doped with the p-type dopant, predetermined voltages may be applied to the first and second electrodes 150 and 170 such that an inversion region of electrons may be formed in the upper portion of the semiconductor region 110 of the first MOS capacitor and an accumulation region of holes may be formed in the lower portion of the semiconductor region of the second MOS capacitor. In another case, predetermined voltages may be applied to the first and second electrodes such that an accumulation region of holes may be formed in the upper portion of the semiconductor region 110 of the first MOS capacitor and an inversion region of electrons may be formed in the lower portion of the semiconductor region of the second MOS capacitor.

The unit device 100 according to the above-described embodiment may function as a light emitting device or PD. Hereinafter, aspects of the unit device 100 as the light emitting device and the PD will be separately described.

### Aspect of Unit Device as Light Emitting Device

FIG. 12 is a diagram schematically illustrating a method of operating a unit device according to one embodiment. Referring to FIGS. 10 through 12, by applying a predetermined positive voltage to the first electrode 150 and applying a predetermined negative voltage to the second electrode 170, energy bands of the first insulator 140, the semiconductor region 110, and the second insulator 160 may be deformed so that an inversion region of electrons may be formed in an upper portion of the semiconductor region 110 and an accumulation region of holes may be formed in a lower portion of the semiconductor region 110.

When a thickness T of the semiconductor region 110 is a predetermined small thickness or less, the electrons in the inversion region of the upper portion of the semiconductor region 110 may transition to the lower portion of the semiconductor region 110 and recombine with the holes present in the accumulation region of the lower portion of the semiconductor region 110. Also, the holes in the accumulation region of the lower portion of the semiconductor region 110 may transition to the upper portion of the semiconductor region 110 and recombine with the electrons present in the inversion region of the upper portion of the semiconductor region 110. Thus, by the transition of the electrons or holes, the electrons and the holes may recombine to emit energy as light.

According to one embodiment, the semiconductor region 110 may be formed of doped silicon. Conventionally, silicon is categorized as an indirect-transition semiconductor. During the transition of electrons from a silicon conductive band to a valence band, lattice vibration, such as heat or sound, may be caused, thus reducing the probability of recombining electrons and holes in the silicon. Thus, emitting light from the silicon due to the electron-hole recombination would be difficult. However, according to the present embodiment, when silicon between the first and second electrodes 150 and 170 is formed to a small thickness of about several tens of nm or less, the degree of freedom of electrons and holes in the silicon is reduced due to quantum confinement. Also, when an inversion region of electrons and an accumulation region of holes are respectively formed in upper and lower portions of an energy-level semiconductor region 100, the electrons and the holes are transitioned through tunneling in the inversion region and the accumulation region. Thus, the electrons or the holes may recombine without involving lattice vibration, such as heat or sound, and exhibit similar behavior to a direct transition. As a result, the electron-hole recombination may occur in the silicon, and energy generated due to the electron-hole recombination may be emitted as light. Therefore, the unit device 100 may be used as a light emitting device. Hereinafter, a method of driving the unit device 100 as a light emitting device according to one embodiment will be described in detail.

The method of driving the light emitting device includes applying a voltage to allow the flow of a forward current between the source and drain regions 120 and 130 of the unit device 100. According to one embodiment, the source region 120 may be formed of silicon heavily doped with an n-type dopant, the drain region 130 may be formed of silicon heavily doped with a p-type dopant, and the semiconductor region 110 may be formed of silicon lightly doped with a p-type dopant. In this case, a higher voltage may be applied to the drain region 130 than the source region 120 so that a forward current may flow between the source and drain regions 120 and 130. Alternatively, the source region 120 may be formed of silicon heavily doped with the p-type dopant, the drain region 130 may be formed of silicon heavily doped with the n-type dopant, and the semiconductor region 110 may be formed of silicon lightly doped with the p-type dopant. In this case, a higher voltage may be applied to the source region 120 than the drain region 130 so that a forward current may flow between the source and drain regions 120 and 130.

Next, a predetermined voltage is applied to each of the first and second electrodes 150 and 170 of the unit device 100 to change a distribution state of electrons and holes in upper and lower portions of the semiconductor region 110. According to one embodiment, the semiconductor region 110 may be formed of silicon lightly doped with a p-type dopant, and the first and second electrodes 150 and 170 may be formed of tungsten. In this case, a predetermined positive voltage is applied to the first electrode 150 and a predetermined negative voltage is applied to the second electrode 170 so that an inversion region of the electrons may be formed in the upper portion of the semiconductor region 110 and an accumulation region of the holes may be formed in the lower portion of the semiconductor region 110. In another case, a predetermined negative voltage is applied to the first electrode 150 and a predetermined positive voltage is applied to the second electrode 170 so that the accumulation region of the holes may be formed in the upper portion of the semiconductor region 110 and the inversion region of the electrons may be formed in the lower portion of the semiconductor region 110.

In this case, when the semiconductor region 110 has a small thickness T of about several tens of nm or less, the degree of freedom of electrons and holes in the semiconductor region 110 formed of silicon may be reduced due to quantum confinement, and tunneling of the electrons and the holes may occur between the inversion region of the electrons and the accumulation region of the holes, which are formed in the upper or lower portion of the semiconductor region 110. That is, the electrons in the inversion region of the electrons may pass through the semiconductor region 110 and recombine with the holes due to the tunneling, while the holes in the accumulation region of the holes may pass through the semiconductor region 110 and recombine with the electrons due to the tunneling. The energy generated due to the electron-hole recombination may be emitted as light.

According to one embodiment, a voltage applied to the first electrode 150 or the second electrode 170 may be adjusted to control the size of the inversion region or accumulation region of the electron or holes formed in the upper or lower portion of the semiconductor region 110. As the area of the inversion region or the accumulation region increases, the density of the electrons or holes present in the inversion region or the accumulation region may also increase. Thus, when the size of the inversion region or the accumulation region is increased, since recombination of the electrons and the holes increases, the amount of light emitted by the unit device 100 may increase. As a result, by adjusting the voltage applied to the first electrode 150 or the second electrode 170, the amount of light emitted by the unit device 100 as the light emitting device may be controlled. Thus, since light is generated due to the recombination of the electrons and the holes in the inversion region or the accumulation region, surface emission may occur throughout the entire area of the semiconductor region 110 where the electron-hole recombination substantially occurs. A light emitting device may be capable of operating at a lower voltage and consuming lower power in the case of surface emission than in the case of linear emission.

### Aspect Of Unit Device as Photodiode (PD)

When light is externally applied to a unit device 100, a semiconductor region 110 may absorb the applied light and generate electron-hole pairs. Specifically, an inversion region of electrons or an accumulation region of holes is generated in an upper portion or lower portion of a semiconductor region 110 and an electric field is formed in the semiconductor region 110 due to predetermined positive and negative voltages applied respectively to the first and second electrodes 150 and 170 of the unit device 100. Also, when light is externally applied, the semiconductor region 110 may absorb the applied light and generate electron-hole pairs. In this case, the generated electrons may move to the inversion region of the electrons generated in the upper or lower portion of the semiconductor region 110 due to the formed electric field, while the generated holes may move to the accumulation region of the holes formed on the opposite side of the inversion region of the electrons.

When a predetermined potential difference occurs between the source and drain regions 120 and 130, the electrons or holes which moved to the inversion region of the electrons or the accumulation region of the holes may conduct as conductive carriers toward the source region 120 or the drain region 130. Thus, the unit device 100 may serve as a PD that reacts with the externally applied light and generate current. Hereinafter, a method of driving the unit device 100 as a PD according to one embodiment will be described in detail.

To begin with, predetermined voltages are respectively applied to the first and second electrodes 150 and 170 of the unit device 100 to change distribution states of electrons and holes in the upper and lower portions of the semiconductor region 110. According to one embodiment, the semiconductor region 110 may be formed of silicon lightly doped with a p-type dopant, and the first and second electrodes 150 and 170 may be formed of tungsten. In this case, a predetermined positive voltage may be applied to the first electrode 150 and a predetermined negative electrode may be applied to the second electrode 170 so that the inversion region of the electrons may be formed in the upper portion of the semiconductor region 110 and the accumulation region of the holes may be formed in the lower portion of the semiconductor region 110. Alternatively, a predetermined negative voltage may be applied to the first electrode 150 and a predetermined positive voltage may be applied to the second electrode 170 so that the accumulation region of the holes may be formed in the upper portion of the semiconductor region 110 and the inversion region of the electrons may be formed in the lower portion of the semiconductor region 110. Also, an electric field may be formed in the semiconductor region 110 due to the voltages applied to the first and second electrodes 150 and 170.

Thereafter, light is applied to the unit device 100. The semiconductor region 110 of the unit device 100 may absorb the light to form electron-hole pairs. The formed electrons and holes move in opposite directions due to the electric field formed in the semiconductor region 100. According to one embodiment, the formed electrons may move to the inversion region of the electrons formed in the upper or lower portion of the semiconductor region 110, while the formed holes may move to the accumulation region of the holes formed on the opposite side of the inversion region of the electrons out of the upper and lower portions of the semiconductor region 110.

Also, voltages are respectively applied to the source and drain regions 120 and 130 to cause a potential difference therebetween. Due to the potential difference, the electrons and holes that have moved to the inversion region of the electrons and the accumulation region of the holes may conduct as components of current toward the source region 120 or the drain region 130.

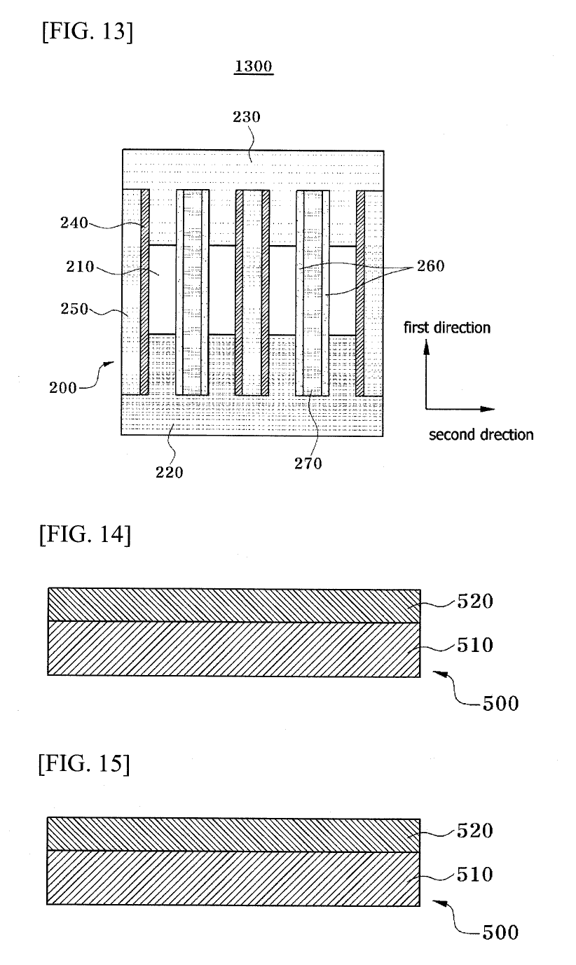

FIG. 13 is a diagram schematically illustrating a semiconductor device as an aggregate of at least two unit devices according to one embodiment. Referring to FIG. 13, a semiconductor device 1300 may be obtained by combining at least two unit devices 100 shown in FIGS. 10 and 11. The semiconductor device 1300 may include at least two unit devices 200. First and second electrodes of the at least two unit devices 200 are alternately disposed facing each other in a first direction. The unit device 200 includes a semiconductor region 210, source and drain regions 220 and 230, a first insulator 240, a second insulator 260, a first electrode 250, and a second electrode 270. Since the unit device 200 has substantially the same construction as the unit device 100, a detailed description thereof will be omitted.

The source and drain regions 220 and 230 are connected to the at least two unit devices 200 in common with each other. Thus, the same voltage may be applied to the source regions 220 or the drain regions 230 of the at least two unit devices 200. Also, the same voltage may be applied to first electrodes of the at least two unit devices 200. Similarly, the same voltage may be applied to second electrodes of the at least two unit devices 200.

According to one aspect of the disclosed technology, the semiconductor device 1300 may function as a light emitting device. The semiconductor region 210 in the at least two unit devices 200 may emit light due to recombination of the electrons and the holes. According to one embodiment, the at least two first electrodes 250 and the at least two second electrodes 270 may be formed of a material that may transmit light. The material that may transmit light may be a transparent conductive material, such as poly-Si, ITO, IZO, ZnO, or In₂O₃. Also, the semiconductor device 400 may further include mirrors (not shown) disposed on both ends of the at least two unit devices 200 arranged in the first direction. Thus, light emitted from the at least two semiconductor regions 210 may travel horizontally in the first direction. The light traveling in the horizontal direction may be reflected by the mirrors disposed on both terminals of the at least two unit devices 200 and reciprocate horizontally in the first direction within the semiconductor device 400. The intensity of the reciprocated light may be increased due to light interference, and light having a specific wavelength and intensity may be selectively extracted from the semiconductor device 400.

According to another embodiment, the at least two first and second electrodes 250 and 270 may be formed of a metal. The metal may be, for example, tungsten (W), silver (Ag), gold (Au), copper (Cu), aluminum (Al), platinum (Pt), titanium (Ti), or tantalum (Ta). Thus, light emitted from the at least two semiconductor regions 210 may travel in a second direction along an interface between the at least two first electrodes 250 and the first insulators 240 or an interface between the at least two second electrodes 270 and the second insulators 260 due to surface plasmon and be externally emitted. Surface plasmon is a phenomenon in which plasmons, which are collective vibration of an electron gas surrounding lattices of metal atoms, combine with light to form polaritons and the polaritons travel along the surfaces of the metal atoms. As a result, the semiconductor device 1300 according to the present embodiment may externally emit the light generated due to the electron-hole recombination in a second direction.

The semiconductor device 1300 functioning as a light emitting device may apply a common voltage to the first electrode 250, the second electrode 270, the source region 220, and the drain region 230 of a plurality of unit devices. Thus, as the number of the unit devices 200 increases, the intensity of light generated by each of the unit devices 200 may be increased.

According to another aspect of the disclosed technology, the semiconductor device 1300 may act as a PD. Each of the unit devices 200 may cause current to flow between the source and drain regions 220 and 230 in response to the externally applied light. The semiconductor device 1300 may have common source and drain regions 220 and 230 and apply a common voltage to the common source and drain regions 220 and 230. Thus, by increasing the number of the unit devices 200, the amount of current that is generated due to the externally applied light and collected by the common source region 220 or the common drain region 230 may be increased.

As described above, the semiconductor device according to the above-described embodiments of the disclosed technology may operate as a light emitting device or PD. The semiconductor device may include at least two unit devices, and each of the unit devices may include a semiconductor region and first and second electrodes. Each of the first and second electrodes may include an inversion or accumulation region of any one of electrons and holes formed in upper and lower portions of the semiconductor region.

When the semiconductor device is used as a light emitting device, a voltage applied to the semiconductor region may be adjusted by the first and second electrodes in such a way as to control the intensity of light emitted from the semiconductor region. Also, the semiconductor device may increase the intensity of emitted light by increasing the number of the unit devices. Furthermore, since the semiconductor device emits light due to the electron-hole recombination between the inversion and accumulation regions, light may be emitted throughout the entire area of the semiconductor region where the electron-hole recombination substantially occurs. Thus, the semiconductor device enables surface emission so that the semiconductor device may operate at a lower voltage and consume lower power than linear emission. In addition, since a standard complementary metal-oxide-semiconductor (CMOS) process using silicon may be applied to the semiconductor device, a high-performance light emitting device may be formed at a low cost.

When the semiconductor device is used as a PD, voltages applied to the first and second electrodes may be adjusted to control an electric field formed in the semiconductor region. Thus, electrons and holes that are generated in the semiconductor region in response to externally applied light may move to the inversion or accumulation region so that the amounts of the electrons and holes collected in the source or drain region may be controlled. Furthermore, the semiconductor device may increase the amount of current generated due to the applied light by increasing the number of the unit devices. Moreover, since the semiconductor device according to the disclosed technology may be used as a light emitting device and a PD, it can be applied to optical communication and remote measuring between at least two semiconductor devices.

Hereinafter, a method of manufacturing a semiconductor device according to one embodiment of the disclosed technology will be described.

FIGS. 14, 16, 18, 20, 22, 24, and 26 are plan views schematically illustrating a method of manufacturing a semiconductor device according to one embodiment, and FIGS. 15, 17, 19, 21, 23, 25, and 27 are cross-sectional views schematically illustrating a method of manufacturing a semiconductor device according to one embodiment. FIGS. 15, 17, 19, 21, 23, 25, and 27 are cross-sectional views taken along line B-B′ of the plan views of FIGS. 14, 16, 18, 20, 22, 24, and 26, respectively.

Referring to FIGS. 14 and 15, a substrate 500 is provided. The substrate 500 is a p-type silicon substrate lightly doped with a p-type dopant. An n-type dopant is heavily doped into the substrate 500 to form a high-concentration n-type doping region 520 in an upper portion of the substrate 500. Thus, the substrate 500 is divided into a low-concentration p-type doping region 510 and the high-concentration n-type doping region 520. The p-type dopant may include boron (B), aluminum (Al), or gallium (Ga). The n-type dopant may include phosphorus (P) or arsenic (As). The doping of the n-type dopant may be, for example, performed by an ion implantation process or a thermal diffusion process using a doping gas.

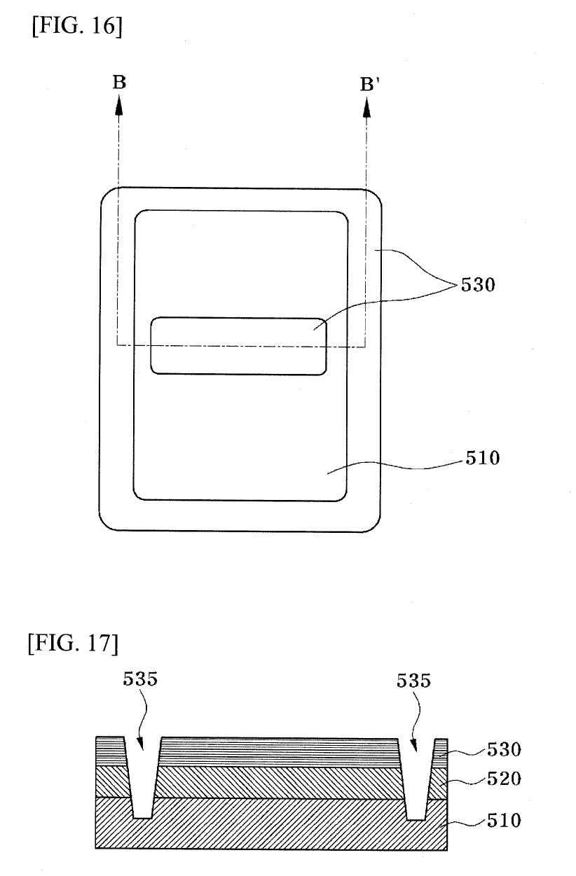

Referring to FIGS. 16 and 17, a first insulating layer 530 is formed on a portion of the high-concentration n-type doping region 520. The first insulating layer 530 may be an oxide layer, a nitride layer, or a combination thereof. For example, the first insulating layer 530 may be a silicon oxide layer, a silicon nitride layer, or a combination thereof.

After forming the first insulating layer 530, isolation trench patterns 535 are formed. The formation of the isolation trench patterns 535 includes selectively etching the low-concentration p-type doping region 510, the high-concentration n-type doping region 520, and the first insulating layer 530 using a lithography process and an anisotropic etching process.

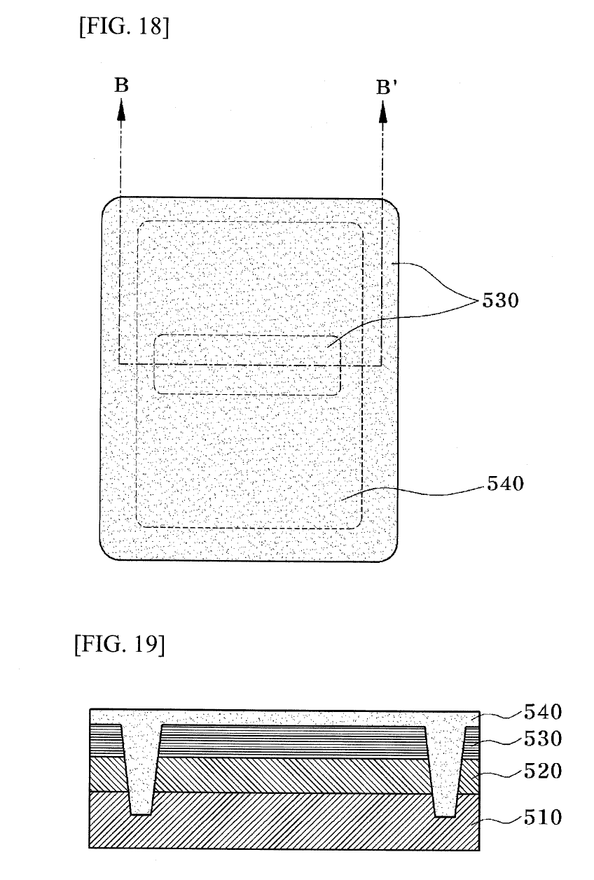

Referring to FIGS. 18 and 19, an isolation oxide layer 540 is formed on the substrate 500. In order to form the isolation oxide layer 540, an oxide layer is formed in the isolation trench patterns 535 and on the first insulating layer 530. After the isolation trench patterns 535 are filled with the oxide layer, the oxide layer formed on the first insulating layer 530 is planarized to form the isolation oxide layer 540 having a predetermined thickness on the first insulating layer 530. The planarization process may be performed using a chemical mechanical polishing (CMP) process.

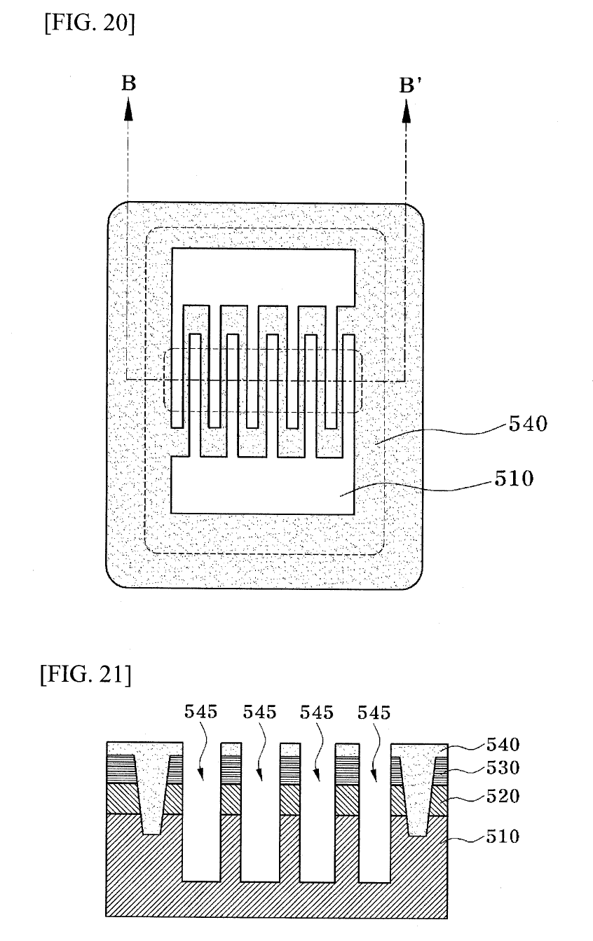

Referring to FIGS. 20 and 21, electrode trench patterns 545 are formed. The formation of the electrode trench patterns 545 includes selectively etching the low-concentration p-type doping region 510, the high-concentration n-type doping region 520, the first insulating layer 530, and the isolation oxide layer 540 using a lithography process and an anisotropic etching process. The electrode trench patterns 545 may be formed to a greater depth than the isolation trench patterns 535.

According to one embodiment, after performing the lithography process and the anisotropic etching process, an oxidation process may be further performed. In this case, portions of the low-concentration p-type doping region 510 and the high-concentration n-type doping region 520 corresponding to a sidewall between one electrode trench pattern 545 and another electrode trench pattern 545 may be oxidized. By etching the oxidized sidewall, an inner trench width of the electrode trench patterns 545 may be increased in a horizontal direction. Thus, the widths of the low-concentration p-type doping region 510 and the high-concentration n-type doping region 520 between the one electrode trench pattern 545 and the other electrode trench pattern 545 may be reduced. The low-concentration p-type doping region 510 and the high-concentration p-type doping region 520 are regions of the unit devices 100 and 200 where the source regions 120 and 220, the drain regions 130 and 230, and the semiconductor regions 110 and 210 are formed described with reference to FIGS. 10 through 13.

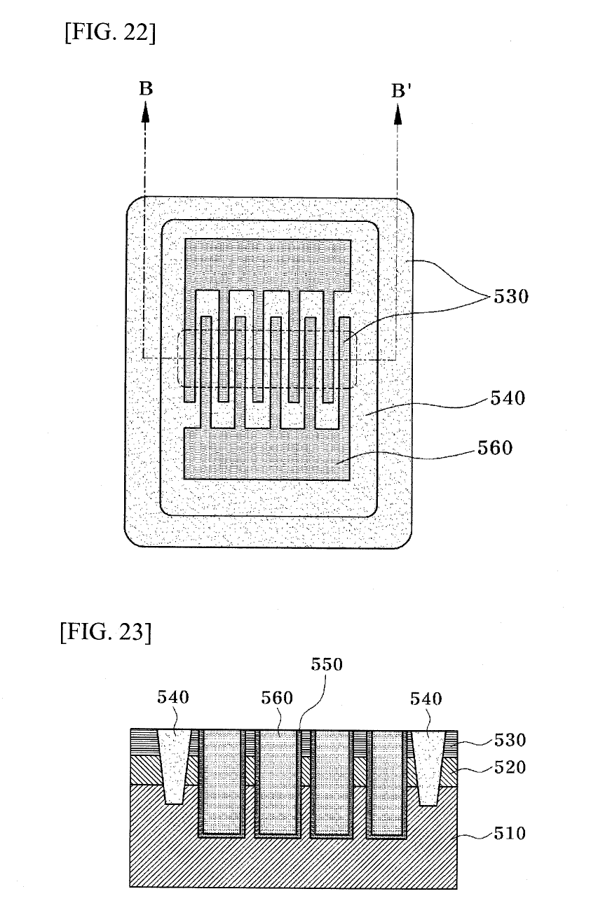

Referring to FIGS. 22 and 23, an electrode insulating layer 550 is formed in the electrode trench patterns 545 of FIG. 23. The electrode insulating layer 550 functions as the first insulators 140 and 240 and the second insulators 160 and 260 of the unit devices 100 and 200 described with reference to FIGS. 10 through 13. The formation of the electrode insulating layer 550 may include thermally oxidizing the low-concentration p-type doping region 510 and the high-concentration n-type doping region 520 in the electrode trench patterns 545 or depositing an oxide layer on the low-concentration p-type doping region 510 and the high-concentration n-type doping region 520 using a chemical vapor deposition (CVD) process or an atomic layer deposition (ALD) process.

Thereafter, an electrode layer 560 is formed. The formation of the electrode layer 560 includes filling the electrode trench patterns 545 in which the electrode insulating layer 550 is formed with an electrode material and removing the electrode material from the first insulating layer 530. The electrode material may include doped silicon or metal. The metal may include tungsten, silver, gold, copper, aluminum, platinum, titanium, or tantalum. The removal of the electrode material from the first insulating layer 530 may be performed using a CMP process. The electrode layer 560 corresponds to the first electrode 150 and 250 or the second electrode 170 and 270 formed in the unit devices 100 and 200 described with reference to FIGS. 10 through 13.

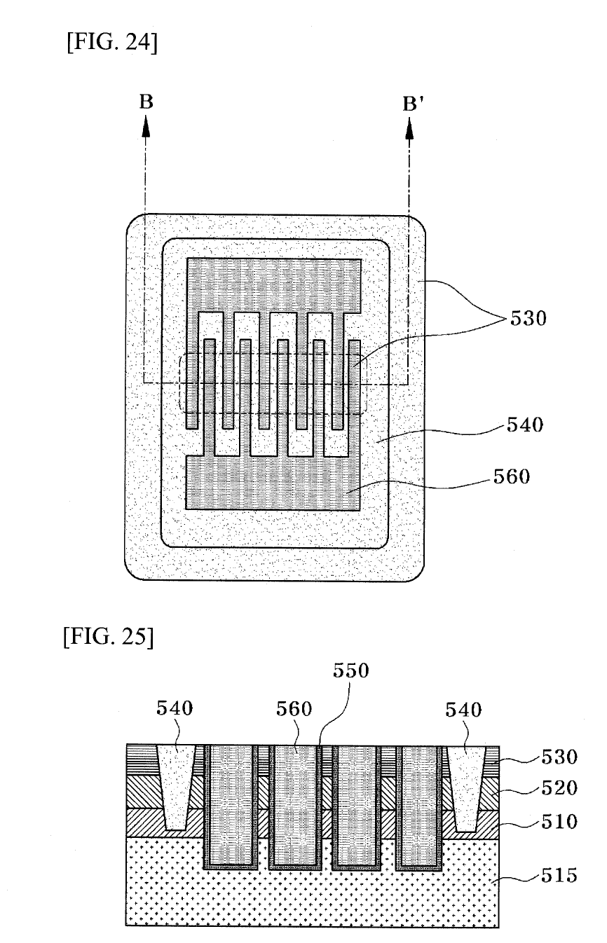

Referring to FIGS. 24 and 25, a partial region of the low-concentration p-type doping region 510 of FIG. 25 is heavily doped with a p-type dopant, thereby forming a high-concentration p-type doping region 515. As shown, the high-concentration p-type doping region 515 is formed under the low-concentration p-type doping region 510. The low-concentration p-type doping region 510 corresponds to the semiconductor regions 110 and 210 formed in the unit devices 100 and 200 described with reference to FIGS. 10 through 13, while the high-concentration p-type doping region 515 or the high-concentration n-type doing region 520 corresponds to the source regions 120 and 220 or the drain regions 130 and 230 formed in the unit devices 100 and 200.

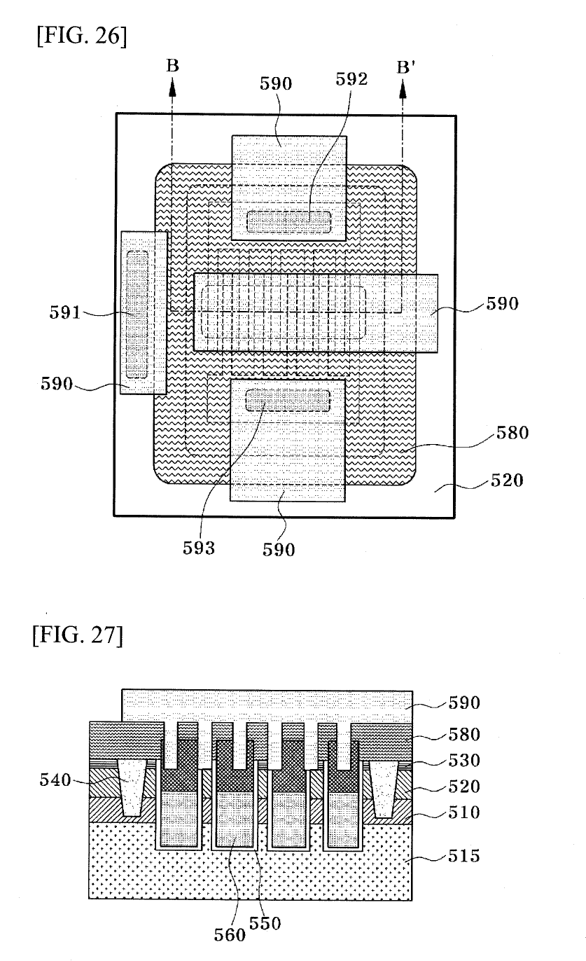

Referring to FIGS. 26 and 27, an interconnection is formed between unit devices of the semiconductor device. The electrode layers 560 of FIGS. 24 and 25 are partially etched and filled with a second insulating layer 570. A third insulating layer 580 is formed on the second insulating layer 570. The second and third insulating layers 570 and 580 may be formed of oxide or nitride. Thereafter, the second and third insulating layers 570 and 580 may be partially etched to form a contact. The contact is filled with a conductive material, and lithography and anisotropic etching processes may be performed to form an interconnection pattern 590. As shown in FIG. 26, the interconnection pattern 590 is connected to the high-concentration n-type doping region 520. Also, as shown in FIG. 26, the interconnection pattern 590 is connected to a high-concentration p-type contact region 591 to form an electric interconnection along with the high-concentration p-type doping region 515. Furthermore, the interconnection pattern 590 may be connected to a first electrode contact region 592 to faun an electrical interconnection along with a region of the electrode layer 560, which functions as a first electrode. In addition, the interconnection pattern 590 may be connected to a second electrode contact region 593 to form an electrical interconnection along with a region of the electrode layer 560, which functions as a second electrode. As a result, semiconductor device including at least two unit devices may be formed.

While the invention has been shown and described with reference to m certain embodiments thereof, it will be understood by those skilled in the art that various changes in form and details may be made therein without departing from the spirit and scope of the invention as defined by the appended claims.

1. A light emitting device, comprising:
a p-type semiconductor;
an n-type semiconductor;
a semiconductor film connected between the p-type semiconductor and the n-type semiconductor;
a first electrode disposed on the semiconductor film and configured to apply an electric field to the semiconductor film; and
a second electrode disposed under the semiconductor film and configured to apply an additional electric field to the semiconductor film.

2. The device according to claim 1, further comprising:
a first insulator disposed between the first electrode and the semiconductor film; and
a second insulator disposed between the second electrode and the semiconductor film.

3. The device according to claim 1, wherein a first voltage for allowing one of inversion and accumulation to occur in an upper portion of the semiconductor film is applied to the first electrode, and a second voltage for allowing the other of the inversion and the accumulation to occur in a lower portion of the semiconductor film is applied to the second electrode.

4. The device according to claim 3, wherein light is emitted due to electron-hole recombination caused by tunneling between the upper and lower portions of the semiconductor film.

5. The device according to claim 1, wherein a first voltage applied to the first electrode differs from a second voltage applied to the second electrode.

6. The device according to claim 1, wherein the semiconductor film is doped with p-type or n-type impurities.

7. The device according to claim 1, wherein a voltage for allowing the flow of a forward current is applied to the p-type semiconductor and the n-type semiconductor.

8. The device according to claim 1, wherein the p-type semiconductor, the n-type semiconductor, and the semiconductor film are formed of silicon.

9. The device according to claim 1, wherein each of the p-type semiconductor and the n-type semiconductor is connected to a lateral surface of the semiconductor film.

10. A light emitting method, comprising:
(a) providing a p-type semiconductor, an n-type semiconductor, and a semiconductor film connected between the p-type and n-type semiconductors; and
(b) applying a voltage for allowing the flow of a forward current to the p-type and n-type semiconductors, allowing one of inversion and accumulation to occur in an upper portion of the semiconductor film, and allowing the other of the inversion and the accumulation to occur in a lower portion of the semiconductor film to permit the semiconductor film to emit light.

11. The method according to claim 10, wherein in step (b), the semiconductor film emits light due to electron-hole recombination caused by tunneling between the upper and lower portions of the semiconductor film.

12. The method according to claim 10, wherein in step (b),
one of the inversion and the accumulation occurs in a top surface of the semiconductor film due to a first voltage applied to a first electrode spaced apart from the semiconductor film by a first insulator, and
the other of the inversion and the accumulation occurs in a bottom surface of the semiconductor film due to a second voltage applied to a second electrode spaced apart from the semiconductor film by a second insulator.

13. A light emitting method, comprising:
(a) providing a p-type semiconductor, an n-type semiconductor, and a semiconductor film connected between the p-type and n-type semiconductors; and
(b) applying a voltage for allowing the flow of a forward current to the p-type and n-type semiconductors and allowing occurrence of tunneling between upper and lower portions of the semiconductor film to permit the semiconductor film to emit light.

14. A semiconductor device comprising an aggregate of at least two unit devices,
wherein each of the unit devices comprises:
a semiconductor region;
source and drain regions disposed on both end sides of the semiconductor region and configured to provide or collect one of electrons and holes;
a first insulator disposed on the semiconductor region;
a first electrode disposed on the first insulator and configured to change a distribution state of one of the electrons and the holes in an upper portion of the semiconductor region;
a second insulator disposed under the semiconductor region; and
a second electrode disposed under the second insulator and configured to change a distribution state of one of the electrons and the holes in a lower portion of the semiconductor region,
wherein the first and second electrodes of each of the at least two unit devices are alternately arranged to form the aggregate.

15. The device according to claim 14, wherein one of the source and drain regions is an n-type semiconductor, and the other of the source and drain regions is a p-type semiconductor.

16. The device according to claim 15, wherein a voltage is applied to allow the flow of a forward current between the source and drain regions.

17. The device according to claim 14, wherein the first and second electrodes comprise any one selected from the group consisting of doped silicon, a metal, a metal silicide, and a transparent conductive material.

18. The device according to claim 17, wherein the metal comprises any one selected from the group consisting of tungsten (W), silver (Ag), gold (Au), copper (Cu), aluminum (Al), platinum (Pt), titanium (Ti), and tantalum (Ta).

19. The device according to claim 17, wherein the transparent conductive material comprises any one selected from the group consisting of indium tin oxide (ITO), indium zinc oxide (IZO), zinc oxide (ZnO), and indium oxide (In₂O₃).

20. The device according to claim 14, wherein each of the unit devices is a light emitting device configured to emit light from the semiconductor region.

21. The device according to claim 20, wherein a first voltage for allowing inversion or accumulation of one of the electrons and the holes in the upper portion of the semiconductor region is applied to the first electrode, and
a second voltage for allowing inversion or accumulation of one of the electrons and the holes in the lower portion of the semiconductor region is applied to the second electrode.

22. The device according to claim 21, wherein the semiconductor region emits light due to recombination of the electrons inverted in the upper portion of the semiconductor region with the holes accumulated in the lower portion of the semiconductor region or due to recombination of the holes accumulated in the upper portion of the semiconductor region with the electrons inverted in the lower portion of the semiconductor region.

23. The device according to claim 22, wherein the recombination of the electrons and the holes occurs due to transition caused by tunneling of the electrons or the holes between the upper and lower portions of the semiconductor region.

24. The device according to claim 20, wherein a region of the upper portion or lower portion of the semiconductor region where the electrons or the holes are inverted or accumulated is changed by adjusting the first voltage or the second voltage, to control the amount of light emitted from the semiconductor region.

25. The device according to claim 20, wherein the light emitted from the semiconductor region travels along an interface between the first electrode and the first insulator or an interface between the second electrode and the second insulator and is externally emitted.

26. The device according to claim 14, wherein the unit device is a photodiode (PD) configured to generate current in response to externally applied light.

27. The device according to claim 26, wherein a first voltage for allowing inversion or accumulation of one of the electrons and the holes to occur in the upper portion of the semiconductor region is applied to the first electrode, and a second voltage for allowing the inversion or the accumulation of the electrons and the holes to occur in the lower portion of the semiconductor region is applied to the second electrode.

28. The device according to claim 26, wherein electron-hole pairs are generated in the semiconductor region in response to the externally applied light.

29. The device according to claim 26, wherein each of the voltages applied to the first and second electrodes is adjusted to control the amount of current generated due to the electron-hole pairs generated in the semiconductor region.

30. A method of driving a semiconductor device, comprising:
(a) providing an aggregate including at least two unit devices, each unit device including a semiconductor region, source and drain regions disposed on both end sides of the semiconductor region, and a first electrode and a second electrode disposed in upper and lower portions of the semiconductor region;
(b) applying a voltage to allow the flow of a forward current between the source and drain regions of the unit device; and
(c) applying a voltage to each of the first and second electrodes of the unit device to respectively change distribution states of electrons and holes in the upper and lower portions of the semiconductor region,
wherein the first and second electrodes of the at least two unit devices are alternately arranged to form the aggregate.

31. The method according to claim 30, wherein step (c) comprises causing tunneling of the electrons and the holes between the upper and lower portions of the semiconductor region and emitting light due to recombination of the electrons and the holes caused by the tunneling.

32. The method according to claim 31, wherein light emitted from the semiconductor region travels along an interface between the first electrode and a first insulator facing the first electrode or an interface between the second electrode and a second insulator facing the second electrode and is externally emitted.

33. The method according to claim 30, wherein step (c) comprises adjusting each of a first voltage and a second voltage to control the amount of light emitted from the semiconductor region.

34. A method of driving a semiconductor device, comprising:
(a) providing an aggregate including at least two unit devices, each unit device including a semiconductor region, source and drain regions disposed on both end sides of the semiconductor region, and first and second electrodes disposed in upper and lower portions of the semiconductor region; and
(b) applying light to the unit device to generate electron-hole pairs,
wherein the first and second electrodes of the at least two unit devices are alternately arranged to form the aggregate.

35. The method according to claim 34, further comprising (c) applying a voltage to each of the first and second electrodes of the unit device to form an electric field in each of the upper and lower portions of the semiconductor region.
